(19) United States
(12) Patent Application Publication
(10) Pub. No.: US 2011/0127628 A1
(43) Pub. Date: Jun. 2, 2011

(54) ION IMPLANTATION TO CHANGE THE OPTICAL PROPERTIES OF THE PASSIVATION FILMS IN CMOS IMAGER DEVICES

(75) Inventor: GIOVANNI MARGUTTI, Avezzano (IT)

(73) Assignee: APTINA IMAGING CORPORATION, Grand Cayman (KY)

(21) Appl. No.: 12/627,430

(22) Filed: Nov. 30, 2009

(51) Int. Cl. H01L 31/0232; H01L 31/18

(52) U.S. Cl. 257/432; 438/70; 257/E31.127

(57) ABSTRACT

Imager sensor pixels, image sensor and methods for forming image sensors. An image sensor pixel includes a photosensor, a microlens that receives incident light, at least one fabrication layer between the photosensor and the microlens and a passivation layer between the microlens and the at least one fabrication layer. The passivation layer includes a plurality of impurities and passes the incident light from the microlens to the photosensor without substantially redirecting the incident light.

### FIELD OF THE INVENTION

The present invention relates to CMOS imagers and, more particularly, to imager sensor pixels and image sensors having a passivation layer including a plurality of impurities, and methods of forming the same.

### BACKGROUND OF THE INVENTION

Image sensors find applications in a wide variety of fields, including machine vision, robotics, guidance and navigation, automotive applications and consumer products. In many smart image sensors, it is desirable to integrate on-chip circuitry to control the image sensor and to perform signal and image processing on the output image. Charge-coupled devices (CCDs), which have been one of the dominant technologies used for image sensors, however, do not easily lend themselves to large scale signal processing and are not easily integrated with complementary metal oxide semiconductor (CMOS) circuits.

Image sensors are typically formed with an array of pixel cells, containing photosensors, such as photodiodes, where each pixel cell produces a signal corresponding to the intensity of light impinging on that pixel cell, when an image is focused on the array. The signals may then be stored and/or processed, for example, to display a corresponding image or otherwise used to provide information about the image. An amount of charge generated by the photosensor generally corresponds to the intensity of light impinging on the photosensor. Accordingly, it is desirable that light directed to the pixel cells is directed to the photosensor.

### BRIEF DESCRIPTION OF THE DRAWINGS

FIG. 1 is a partial cross-sectional view of an image sensor according to an example embodiment of the invention;

FIGS. 2A and 2B are cross-sectional views of a portion of the image sensor shown in FIG. 1, illustrating the transmission of incident light through the image sensor, according to example embodiments of the invention;

FIGS. 3A, 3B, 3C, 3D and 3E are partial cross-sectional views illustrating fabrication of an image sensor according to an example embodiment of the invention;

FIG. 4 is a flowchart illustrating a method for forming an image sensor according to an example embodiment of the invention;

FIG. 5 is a graph of dispersion as a function of wavelength for various ion implantation energies and concentrations, according to example embodiments of the invention;

FIG. 6 is a block diagram illustrating a CMOS imaging device incorporating at least one image sensor in accordance with an embodiment of the invention.

### DETAILED DESCRIPTION OF THE INVENTION

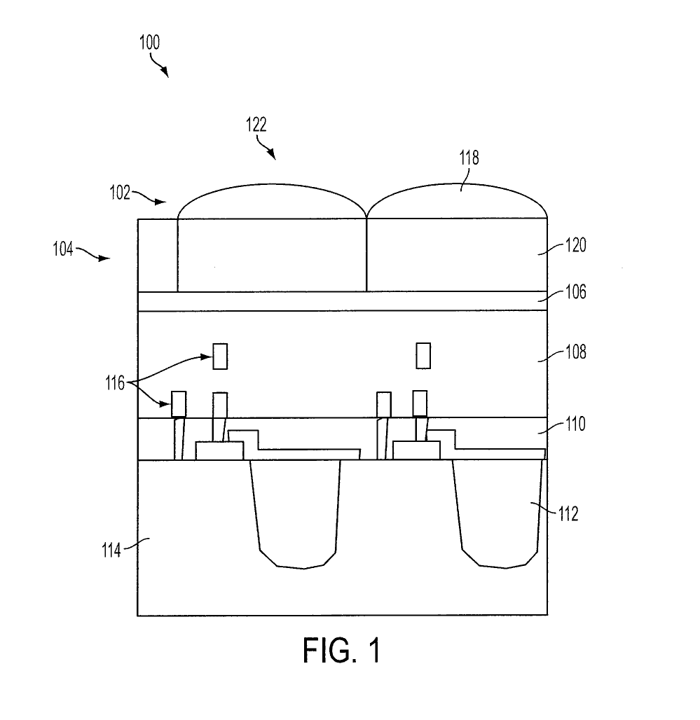

FIG. 1 is a partial cross-sectional view of image sensor 100. Image sensor 100 includes microlens array 102 having a plurality of microlenses 118 and a plurality of photosensors 112. In general, image sensor 100 includes a plurality of pixels 122. Each pixel 122 has a microlens 118 and an associated photosensor 112. Incident light may be directed by microlenses 118 to respective photosensors 112. Photosensors 112 are embedded in substrate 114 and may include photo gates, photo transistors, photo conductors or photo diodes.

Image sensor 100 may also include a color filter array (CFA) 104 having a plurality of color filters 120. CFA 104 may pass incoming light of a particular color(s) to photosensitive portions of corresponding photosensors 112, while blocking light of other colors from reaching respective photosensors 112.

Color filters 120 may be formed in a sequential pattern of red, green and blue filters, for example, such as in a Bayer pattern, with rows of green and red filters alternating with rows of blue and green filters. It is understood that color filters 120 may be formed in any suitable pattern. According to another embodiment, imaging sensor 100 may be one of a plurality of image sensors, with each image sensor 100 including a monochromatic array of color filters 120. Although FIG. 1 illustrates CFA 104, it is understood that the inclusion of CFA 104 may be optional. According to another embodiment, image sensor 100 may not include CFA 104, for example, if image sensor 100 acquires black and white images.

Image sensor 100 may also include one or more fabrication layers, such as insulation layer 108 and protective layer 110, which may be formed over substrate 114 having photosensors 112. In addition, image sensor 100 includes passivation layer 106 formed between CFA 104 and insulation layer 108. Protective layer 110 is typically formed of borophosphosilicate glass (BPSG) and insulation layer 108 is typically formed from an oxide. Insulation layer 108 may include various metal layers 116. Protective layer 110 may also include metal contacts coupled to respective photosensors 112. Those skilled in the art will appreciate that photosensors 112, protective layer 110, insulation layer 108, CFA 104 and microlens array 102 may be formed by any of various methods known in the art.

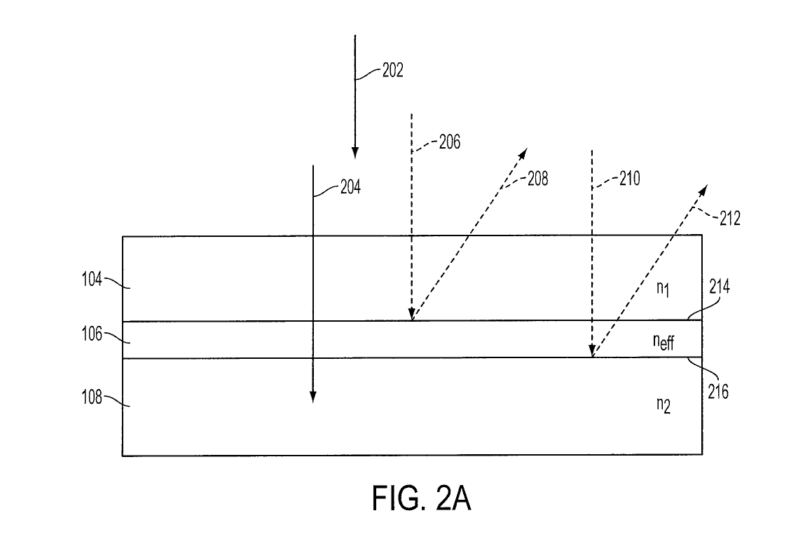

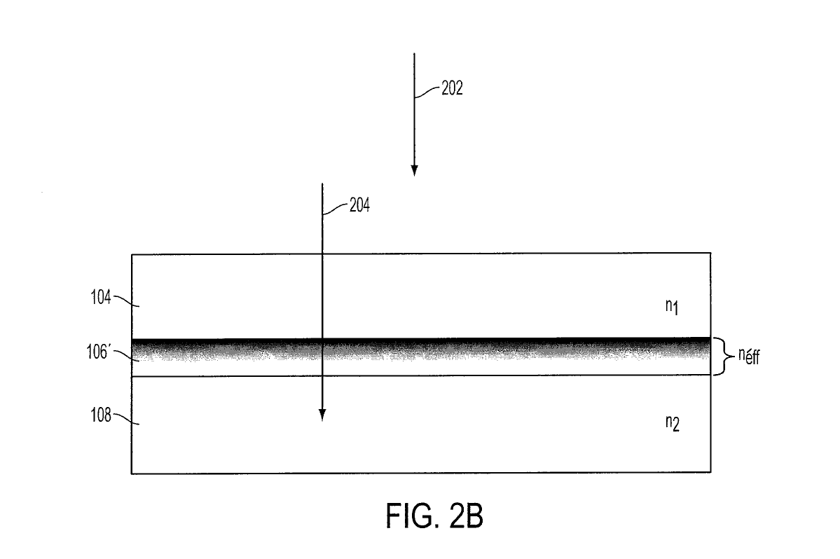

Passivation layer 106 may be formed of an insulating material, such as silicon nitride. According to an example embodiment, passivation layer 106 includes a plurality of impurities, such as argon ions. The impurities may be used to modify a refractive index (n_{eff}) of passivation layer 106. In particular, the refractive index of passivation layer 106 may be modified to substantially match at least one of a refractive index of CFA 104 or a refractive index of insulation layer 108. A further description of an effect on of the optical properties of passivation layer 106 due to the impurities is described further below with respect to FIGS. 2A and 2B.

Referring to FIGS. 2A and 2B, a cross-sectional view of a portion of image sensor 100 (FIG. 1) is shown. FIGS. 2A and 2B illustrate the transmission of incident light 202 through CFA 104, passivation layer 106 (106′) and insulation layer 108, when passivation layer 106 (106′) includes impurities. In particular, FIG. 2A illustrates passivation layer 106 having a single refractive index n_{eff}; and FIG. 2B illustrates a passivation layer 106′ having a graded refractive index represented by n′_{eff}.

In conventional image sensors, a passivation layer typically has a refractive index of about 2.0. In contrast, CFA 104 typically includes a refractive index (n₁) of between about 1.5-1.7, whereas insulation layer 108 typically includes a refractive index (n₂) of about 1.46. Accordingly, the refractive indices n₁ and n₂ of CFA 104 and insulation layer 108 are typically similar. Because the refractive index of the passivation layer in conventional devices is different from the refractive indices n₁ and n₂, incident light 202 may be reflected at an interface 214 (between CFA 104 and a conventional passivation layer) and/or at an interface 216 (between a conventional passivation layer and insulation layer 108).

For example, light 206 may pass through CFA 104 and may be reflected at interface 214, as reflected light 208. Alternately, or in addition to reflected light 208, a portion of light 210 may pass through a conventional passivation layer and may be reflected at interface 216, as reflected light 212.

In contrast to conventional image sensors, passivation layer 106 includes a plurality of impurities. The impurities may be selected such that refractive index n_{eff} of passivation layer 106 substantially matches at least one of refractive index n₁ of CFA 104 or refractive index n₂ of insulation layer 108. Accordingly, refractive index n_{eff} may be selected, via the impurities, to minimize a difference between refractive index n₁ and/or refractive index n₂. In this manner, incident light 202 may be substantially passed through CFA 104, passivation layer 106 and insulation layer 108, as passed light 204, without being substantially reflected. Because n_{eff} of passivation layer 106 substantially matches at least one of n₁ or n₂, incident light 202 may be passed to photosensors 112 (FIG. 1), without being substantially redirected at interface 214 and/or at interface 216.

According to an embodiment of the present invention, impurities may be applied to passivation layer 106 according to one or more impurity conditions. The impurity conditions may include a dosing concentration or an ion implantation energy. As an example, for impurity conditions of an ion implantation energy of 60 KeV and a dose concentration of 5×10¹⁶ atoms/cm2 of argon ions, the refractive index of passivation layer 106 may be decreased from about 2.0 to about 1.69, for green incident light. According to an example embodiment, the impurity conditions may be selected such that refractive index n_{eff} substantially matches at least one of n₁ or n₂ over at least one wavelength band, for example, for green light.

Although FIG. 2A illustrates passivation layer 106 having a single refractive index n_{eff}, image sensor 100 may also include passivation layer 106′, having a graded refractive index n′_{eff}, as shown in FIG. 2B. For example, passivation layer 106′ may include two or more sub-layers with different impurity conditions, which have different refractive indices. Accordingly, passivation layer 106′ may be represented by an overall effective refractive index of n′_{eff} In general, n′_{eff} is approximately equal to a weighted average of the refractive indices of each sub-layer of passivation layer 106′, depending on the relative contributions of the refractive indices to the average.

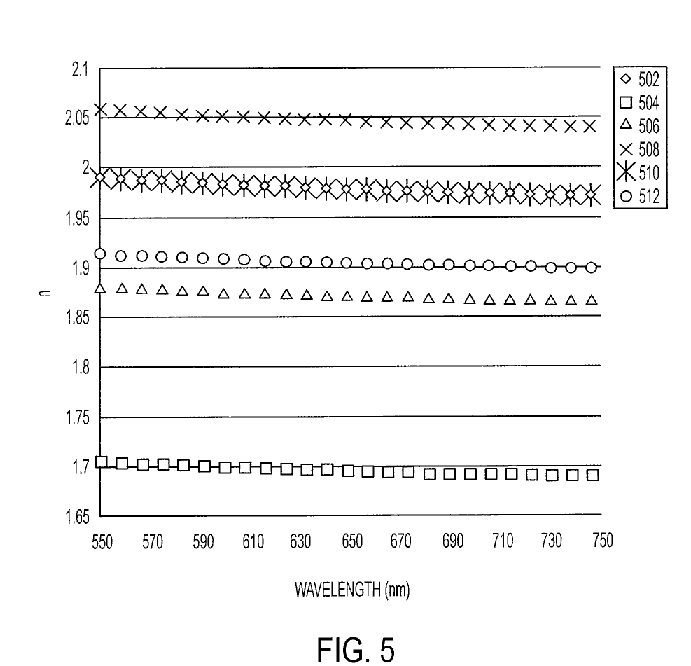

For example, if passivation layer 106′ (FIG. 2B) is formed from two sub-layers, a bottom layer and a top layer, the refractive index for each of these sub-layers may be adjusted according to the impurity conditions. Referring to FIG. 5, dispersion curves of the refractive index as a function of wavelength is shown for various impurity conditions, for each of a bottom sub-layer and top sub-layer of passivation layer 106′. For example, curves 502, 506 and 510 represent the dispersion curves for the bottom sub-layer under respective implantation energy/dosing concentrations of 40 KeV/5×10¹⁶ atoms/cm², 200 KeV/3×10¹⁶ atoms/cm² and 40 KeV/2×10¹⁶. Curves 504, 508 and 512 represent dispersion curves for the top sub-layer under the same corresponding conditions. In FIG. 5, curve 502 relates to a sub-layer thickness of about 1600±50 angstrom (A), curve 504 relates to a sub-layer thickness of about 900±50 A, curve 506 relates to a sub-layer thickness of about 650±50 A, curve 508 relates to a sub-layer thickness of about 1650±50 A, curve 510 relates to a sub-layer thickness of about 700±50 A and curve 512 relates to a sub-layer thickness of about 1600±50 A. As shown in FIG. 5, the refractive index of each sub-layer may be adjusted according to one or more of the ion implantation energy and dosing concentrations.

Referring back to FIG. 1, according to another embodiment, passivation layer 106 may be formed with different impurity conditions for different respective color filters 120. According to yet another embodiment, different impurity conditions may be applied to passivation layer 106 in different regions of image sensor 100. For example, different impurity conditions may be applied to pixels near a center of image sensor 100 as opposed to pixels near a periphery of image sensor 100. According to yet another embodiment, passivation layer 106 may be formed with impurities in at least a portion of image sensor 100 and without impurities in a different portion of image sensor 100. According to a further embodiment, different types of ions may be implanted in different regions of passivation layer 106.

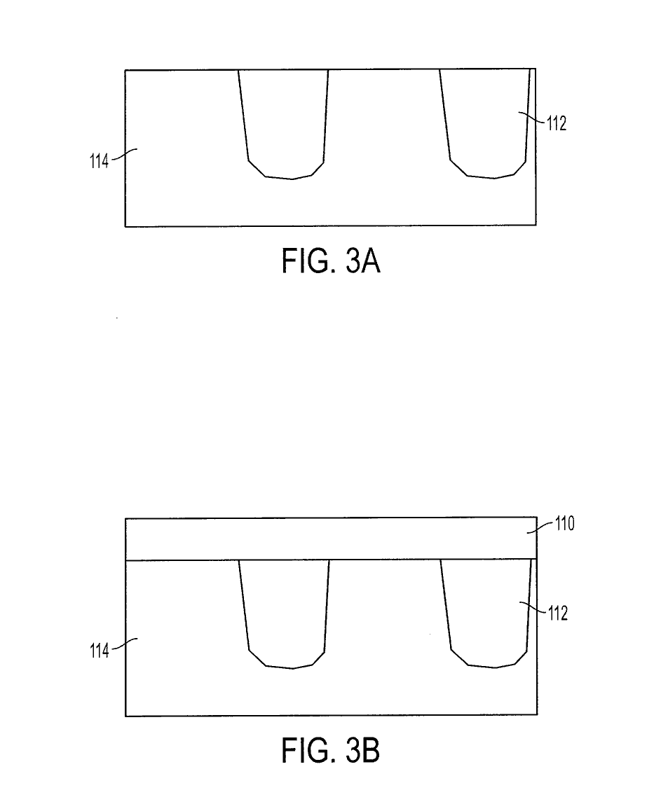

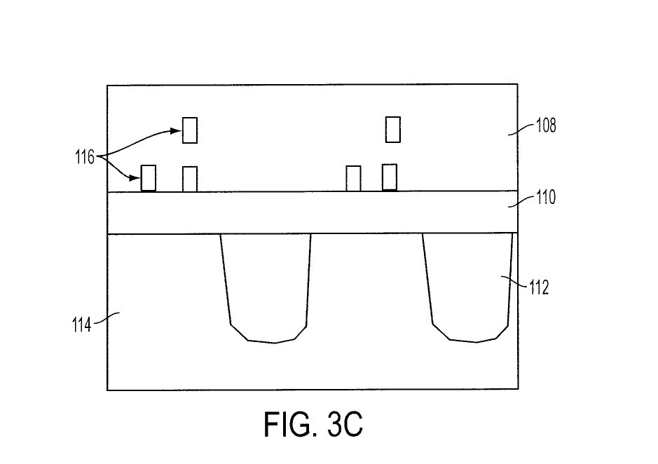

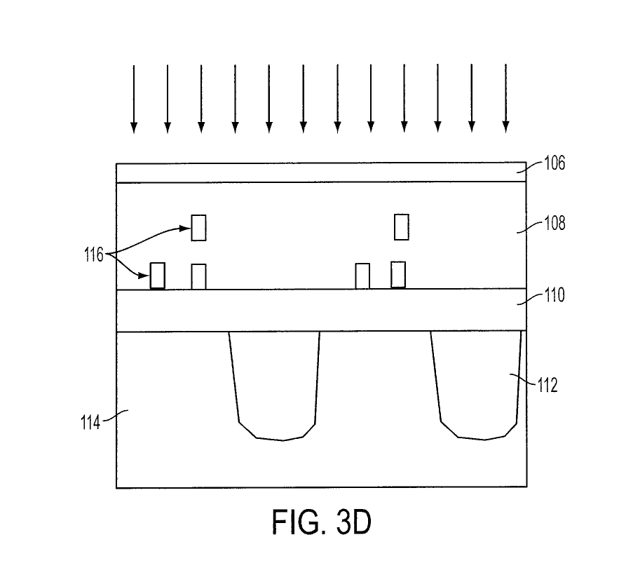

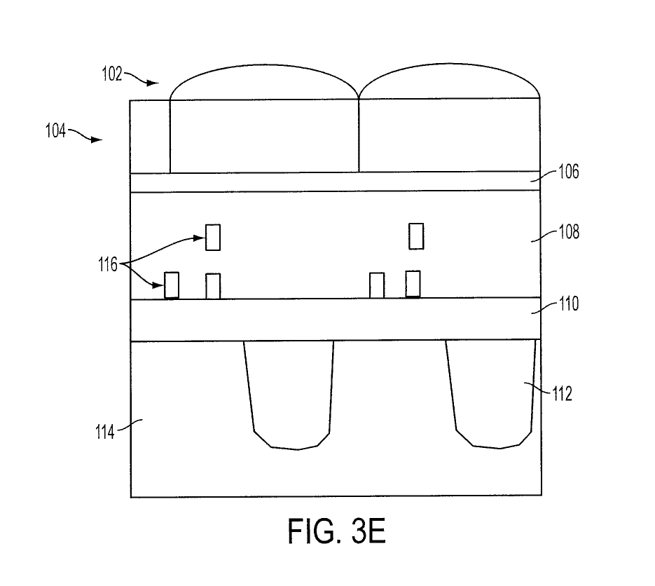

Referring next to FIGS. 3A-3E, partial cross-sectional views of image sensor 100 are shown, illustrating a process for manufacturing image sensor 100. As shown in FIG. 3A, photosensors 112 may be formed for each pixel 122 on substrate 114. Substrate 114 may include any suitable semiconductor substrate.

Referring to FIG. 3B, protective layer 110 is formed over photosensors 112. Although not shown in FIG. 3B, contacts to photosensors 112 may also be formed in protective layer 110.

Referring to FIG. 3C, insulation layer 108 and metal layers 116 are formed over protective layer 110. Metal layers 116 may be formed to penetrate insulation layer 108 and provide signal and power lines to devices formed on substrate 114.

Referring to FIG. 3D, passivation layer 106 may be formed of an insulating material that is optically transparent, such as a silicon nitride layer. Ions of a material, such as argon, may be implanted in passivation layer 106 such that passivation layer 106 includes a plurality of ion impurities. Other example implantation materials may include, but are not limited to, nitrogen (N), molecular nitrogen (N₂), arsenic (As), fluorine (F) and phosphorous (P). The ions may be implanted according to one or more impurity conditions. According to one embodiment, the ion impurities may be implanted to lower refractive index n_{eff} to match at least one of insulation layer 108 or CFA 104.

According to another embodiment, one or more masks, such as a photoresist pattern, may be formed on passivation layer 106 such that ions may be implanted with different impurity conditions to different pixels or regions of image sensor 100. For example, different impurity conditions may be provided to pixels of different color filters 120 (FIG. 1). According to another embodiment, passivation layer 106 may be formed from two or more sub-layers, such that each sub-layer may have impurities implanted with different impurity conditions.

Referring to FIG. 3E, CFA 104 may be formed on passivation layer 106. CFA 104 may be formed in each pixel to separate colors from incident light. For example, color filters 120 may include red, green and blue color filters or may represent a monochromatic filter. Microlens array 102 is formed over CFA 104.

It should be understood that any optically transparent material with a suitable refractive index may be used as microlens array 102, insulation layer 108 and protection layer 110. The formation of photosensors 112, protective layer 110, insulation layer 108, passivation layer 106, CFA 104 and microlens array 102 may be understood by the skilled person from the description herein.

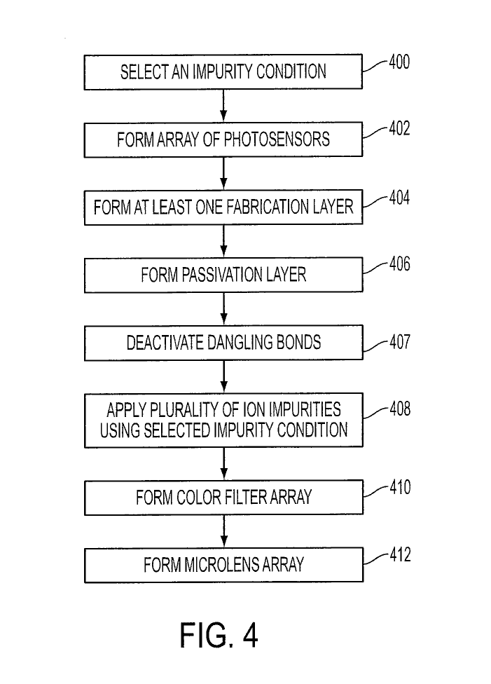

Referring next to FIG. 4, a method of manufacturing an image sensor, according to an example embodiment of the invention is shown. The steps illustrated in FIG. 4 represent an example embodiment of the present invention. It is understood that certain steps may be performed in an order different from what is shown. It is also understood that certain steps may be eliminated.

At step 400, an impurity condition is selected, for example, based on the refractive index of insulation layer 108 (FIG. 1) and/or the refractive index of CFA 104. At step 402, an array of photosensors are formed, for example, photosensors 112 (FIG. 1) may be formed on substrate 114. At step 404, at least one fabrication layer may be formed over the array of photosensors, for example, such as insulation layer 108 (FIG. 1). At step 406, a passivation layer may be formed over the fabrication layer, for example, passivation layer 106 (FIG. 1) may be formed over insulation layer 108.

At step 407, dangling bonds may be deactivated in the substrate, such as substrate 114 (FIG. 1). To deactivate the dangling bonds, the image sensor, as formed, may be subjected to a gas environment under low temperature conditions. According to an example embodiment, a gas containing hydrogen (H₂) or deuterium (D₂), may be diffused into the substrate under a low temperature of about 400° C. The gas may saturate and deactivate silicon dangling bonds in the substrate. The gas may also release a percentage of hydrogen from the passivation layer. Alternatively, step 407 may be performed after step 408.

In an example embodiment, argon ions are implanted in a silicon nitride passivation layer with 40 KeV ion energy and a 5×10¹⁶ atoms/cm² dosing concentration. In this example, the effective refractive index of the impurity-implanted passivation layer is reduced after application of the deactivation step (step 407). The refractive index of each sub-layer (and accordingly the effective refractive index) may be reduced due the diffusion of the gas into the silicon from the nitride by the deactivation step. Results for a two sub-layer passivation layer are shown in Table 1, both prior to and after the deactivation step. Accordingly, application of the gas to deactivate the silicon dangling bonds may also lower the effective refractive index of the passivation layer.

TABLE 1
Refractive Index Prior to and After Deactivation

| | Bottom Layer | n_{sub-layer} at | Top Layer | n_{sub-layer} at |
|---|---|---|---|---|
| | thickness (A) | 550 nm | thickness (A) | 550 nm |
| Pre- | 1633 | 2.06 | 884 | 1.71 |
| deactivation | | | | |
| Post- | 1550 | 2.00 | 1009 | 1.66 |
| deactivation | | | | |

At step 408, a plurality of ion impurities may be applied to the passivation layer based on the selected impurity condition (step 400). At step 410, a color filter array may be formed over the passivation layer having the ion impurities, for example, CFA 104 (FIG. 1) may be formed over passivation layer 106. At step 412, an array of microlenses may be formed over the color filter array, for example, microlens array 102 (FIG. 1) may be formed over CFA 104.

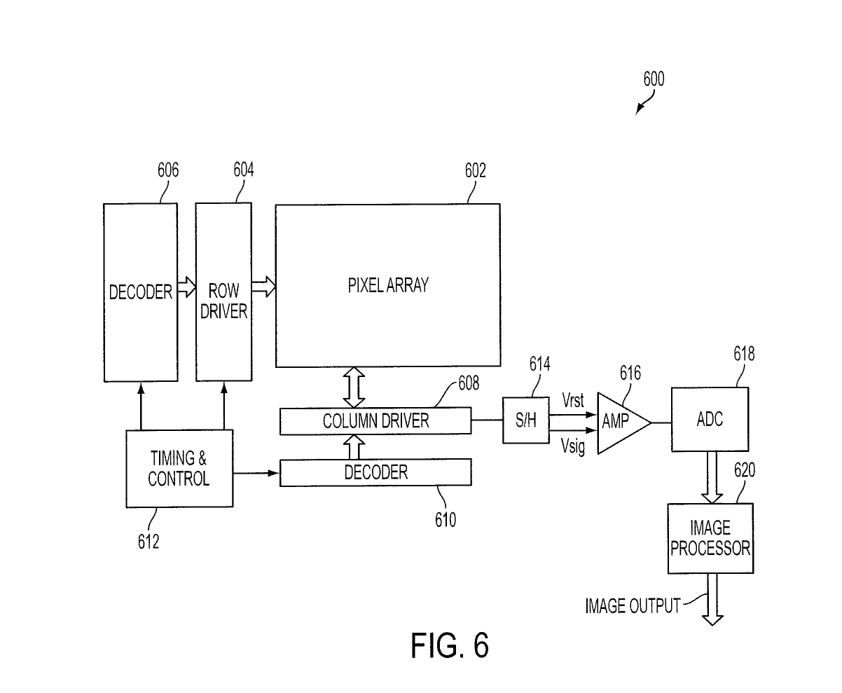

FIG. 6 is a block diagram of a CMOS image device 600 including image sensor 602. Image sensor 602 of image device 600 includes a plurality of pixels arranged as an array in a predetermined number of columns and rows. The pixels of each row in the array are turned on by a row select line and the pixels of each column may be selected for output by a column select line. A column driver 608 and column address decoder 610 are also included in image device 600. A plurality of row and column lines are provided for the entire array. Although a column select line is described, the column select line is optional. Image sensor 602 may include any image sensors in accordance with an embodiment of the invention, such as image sensor 100 (FIG. 1).

The row lines are selectively activated by row driver 604 in response to row address decoder 606. CMOS image device 600 is operated by timing and control circuit 612, which controls address decoders 606, 610 for selecting the appropriate pixels for pixel readout, and row and column driver circuitry, which apply driving voltages to the drive transistors of the selected pixels.

Each column of the array contains sample and hold circuitry (S/H), designated generally as 614, including sample and hold capacitors and switches associated with the column driver that read and store a pixel reset signal (Vrst) and a pixel image signal (Vsig) for selected pixels. A differential signal (reset-signal) is produced by programmable gain amplifier (PGA) circuit 616 for each pixel, which is digitized by analog-to-digital converter (ADC) 618. ADC 618 supplies the digitized pixel signals to image processor 620, which forms and outputs a digital image.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A image sensor pixel comprising:
a photosensor;
a microlens that receives incident light;
at least one fabrication layer between the photosensor and the microlens; and
a passivation layer between the microlens and the at least one fabrication layer, the passivation layer having a plurality of impurities and passing the incident light from the microlens to the photosensor without substantially redirecting the incident light.

2. The image sensor pixel according to claim 1, wherein the plurality of impurities include ions formed from at least one of argon, nitrogen, molecular nitrogen, arsenic, fluorine or phosphorous.

3. The image sensor pixel according to claim 1, wherein the passivation layer is formed from a material including silicon nitride.

4. The image sensor pixel according to claim 1, further comprising a color filter between the microlens and the passivation layer, the color filter passing the incident light to the photosensor in a wavelength band.

5. The image sensor pixel according to claim 1, wherein the at least one fabrication layer is formed from a material including at least one of an oxide or borophosphosilicate glass (BPSG).

6. The image sensor pixel according to claim 1, wherein the plurality of impurities modify a refractive index of the passivation layer.

7. The image sensor pixel according to claim 6, wherein the refractive index of the passivation layer includes a graded refractive index.

8. The image sensor pixel according to claim 6, wherein the refractive index is modified by at least one of a doping concentration of the plurality of impurities or an implantation energy of the plurality of impurities.

9. An image sensor comprising:
a photosensor array;
a color filter array having a first refractive index;
at least one fabrication layer, having a second refractive index, between the color filter array and the photosensor array; and
a passivation layer, having an effective refraction index, between the color filter array and the at least one fabrication layer, the passivation layer having a plurality of impurities in a region of the passivation layer,
wherein the plurality of impurities are selected to substantially match the effective refractive index to at least one of the first refractive index or the second refractive index.

10. The image sensor according to claim 9, wherein the effective refractive index of the passivation layer matches at least one of the first refractive index or the second refractive index in at least one wavelength band.

11. The image sensor according to claim 9, wherein the color filter array includes a plurality of color filters that each pass different wavelength bands, the region of the passivation layer corresponding to at least one of the plurality of color filters.

12. The image sensor according to claim 9, wherein the region includes a first region and a second region, the first region having a different effective refractive index from the second region.

13. The image sensor according to claim 9, wherein the plurality of impurities include ions formed from at least one of argon, nitrogen, molecular nitrogen, arsenic, fluorine or phosphorous.

14. The image sensor according to claim 9, wherein the passivation layer includes at least two sub-layers having different refractive indices, a combination of the different refractive indices forming the effective refractive index.

15. The image sensor according to claim 9, further comprising a microlens array above the color filter array.

16. A method of forming an image sensor, the method comprising:
selecting an impurity condition based on at least one of a first refractive index of a color filter layer or a second refractive index of a fabrication layer;
forming the fabrication layer over an array of photosensors;
forming a passivation layer over the fabrication layer;
applying a plurality of ions to the passivation layer with the selected impurity condition; and
forming a color filter layer over the passivation layer having the plurality of ions.

17. The method according to claim 16, wherein the impurity condition includes at least one of a doping concentration and an implantation energy of the plurality of ions.

18. The method according to claim 16, the forming of the passivation layer and the applying of the plurality of ions including:
forming at least two sub-layers of the passivation layer; and
applying a plurality of ions to the at least two sub-layers with different impurity conditions.

19. The method according to claim 16, the applying of the plurality of ions including applying the plurality of ions to at least one region of the passivation layer.

20. The method according to claim 16, the selecting of the impurity condition includes selecting the impurity condition such that an effective refractive index of the passivation layer with the plurality of ions substantially matches at lest one of the first refractive index or the second refractive index.
